(19) United States
(12) Patent Application Publication
(10) Pub. No.: US 2010/0123175 A1
(43) Pub. Date: May 20, 2010

(54) SEMICONDUCTOR DEVICE

(75) Inventor: Hiroyuki KANAYA, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/557,422

(22) Filed: Sep. 10, 2009

(30) Foreign Application Priority Data
Nov. 14, 2008 (JP) 2008-292026

(51) Int. Cl. H01L 27/108

(52) U.S. Cl. 257/295; 257/E27.084

(57) ABSTRACT

According to an aspect of the present invention, there is provided a semiconductor device, including: a semiconductor substrate; a transistor that is formed on the semiconductor substrate; an interlayer insulating film that is formed on the semiconductor substrate so as to cover the transistor and that has a through hole formed thereinside so as to reach the transistor; a plug lower-electrode that is formed in the through hole and that is connected to the transistor; a ferroelectric film that is formed on the plug lower-electrode; and an upper-electrode that is formed on the ferroelectric film.

### CROSS-REFERENCE TO RELATED APPLICATIONS

This application claims priority from Japanese Patent Application No. 2008-292026 filed on Nov. 14, 2008, the entire contents of which are incorporated herein by reference.

### BACKGROUND OF THE INVENTION

1. Field of the Invention

An aspect of the present invention relates to a semiconductor device having a ferroelectric capacitor.

2. Description of the Related Art

There is known a semiconductor device (hereinafter referred to also as an FeRAM (ferroelectric random access memory)), which stores data using a ferroelectric capacitor in a nonvolatile manner. For example, the FeRAM has a so-called capacitor-on-plug (COP) structure including a switching transistor on a semiconductor substrate, a ferroelectric capacitor formed of a lower-electrode, a ferroelectric film and an upper-electrode and formed on a contact plug connected to the diffusion layer of the transistor, and a barrier film or the like provided to suppress the diffusion of a material that causes oxidation or reduction.

There is high demand for a higher integration of a FeRAM, and the micropatterning of a ferroelectric capacitor is important. In view of that, for example, the ferroelectric capacitor is formed to so that the side surface thereof is formed close to a right angle with the upper surface of a semiconductor substrate, and a ferroelectric film is formed to be thinner. While the micropatterning of a ferroelectric capacitor is demanded, it is important not to worsen the characteristics of the ferroelectric capacitor. That is, it is important to eliminate factors which deteriorate the characteristics of a ferroelectric capacitor.

Factors deteriorating the characteristics of a ferroelectric capacitor include a seam or a void formed in a plug. For example, there is disclosed a semiconductor memory device (see, e.g., JP-2006-210634-A), in which an insulating layer of boron phosphorous silicate glass (BPSG) formed on a semiconductor substrate, a first plug of tungsten (W) formed in a first hole that is formed in the insulating layer, a first hydrogen barrier layer of insulating silicon nitride (SiN) formed on the insulating layer and having a second hole communicating with the first hole, and a second plug formed from a second hydrogen barrier layer of electrically conductive titanium aluminum nitride (TiAlN) and formed in the second hole are formed. Above the first hydrogen barrier layer and the second plug, a lower-electrode of iridium (Ir), iridium oxide (IrO) and platinum (Pt), a capacitive insulating layer of strontium bismuth tantalite (SBT) and an upper-electrode of Pt are formed in this order from the bottom. A seam (or a void) is formed in the first plug, and at least a part of the seam is filled with an insulating material made of SiN.

Generally, a plug used in the semiconductor device is formed by forming a through hole in an interlayer insulating film and by depositing a plug material film in the through hole. The plug material film is deposited on a bottom surface and a side surface of the through hole, and the deposited thickness of the plug material film gradually increases. As a result, for example, at a location where the plug material films being deposited on the opposing sides of the side surface abuts with each other, that is, around the center of the through hole, a seam or a void is formed.

In the disclosed semiconductor device, by burying SiN in a seam (or a void) to not affect the formation of the lower-electrode to be formed thereon, the deterioration of the characteristics of the capacitor is suppressed. However, because the two plugs are formed, i.e., two plug forming processes have been performed, plug misalignment occurs, and the number of processing steps is increased, thereby reducing the manufacturing yield or the like.

### SUMMARY OF THE INVENTION

According to an aspect of the present invention, there is provided a semiconductor device, including: a semiconductor substrate; a transistor that is formed on the semiconductor substrate; an interlayer insulating film that is formed on the semiconductor substrate so as to cover the transistor and that has a through hole formed thereinside so as to reach the transistor; a plug lower-electrode that is formed in the through hole and that is connected to the transistor; a ferroelectric film that is formed on the plug lower-electrode; and an upper-electrode that is formed on the ferroelectric film.

### BRIEF DESCRIPTION OF THE DRAWINGS

FIG. 1 illustrates a cross-sectional view of a semiconductor device according to Embodiment 1.

FIGS. 2A to 2C are cross-sectional views illustrating steps of a method for manufacturing the semiconductor device according to Embodiment 1 in sequential order, focusing on the plug lower-electrode.

FIGS. 3A to 3C are cross-sectional views illustrating steps of the method for manufacturing the semiconductor device according to Embodiment 1 in sequential order, continuing from the steps illustrated in FIGS. 2A to 2C.

FIG. 4 illustrates a cross-sectional view of a semiconductor device according to Embodiment 2.

FIG. 5 illustrates a cross-sectional view of a semiconductor device according to Embodiment 3.

FIGS. 6A to 6C are cross-sectional views illustrating steps of a method for manufacturing a semiconductor device according to Embodiment 3 in sequential order, focusing on the plug lower-electrode.

### DETAILED DESCRIPTION OF THE INVENTION

Hereinafter, embodiments of the invention are described with reference to the accompanying drawings. In each of the drawings, the same constituent elements are designated with the same reference numeral.

### Embodiment 1

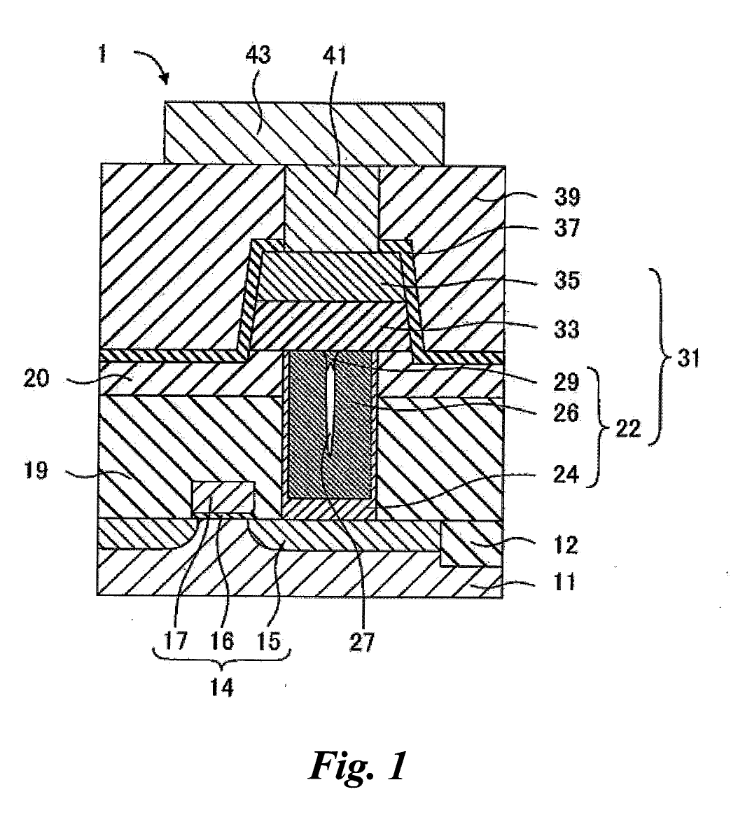

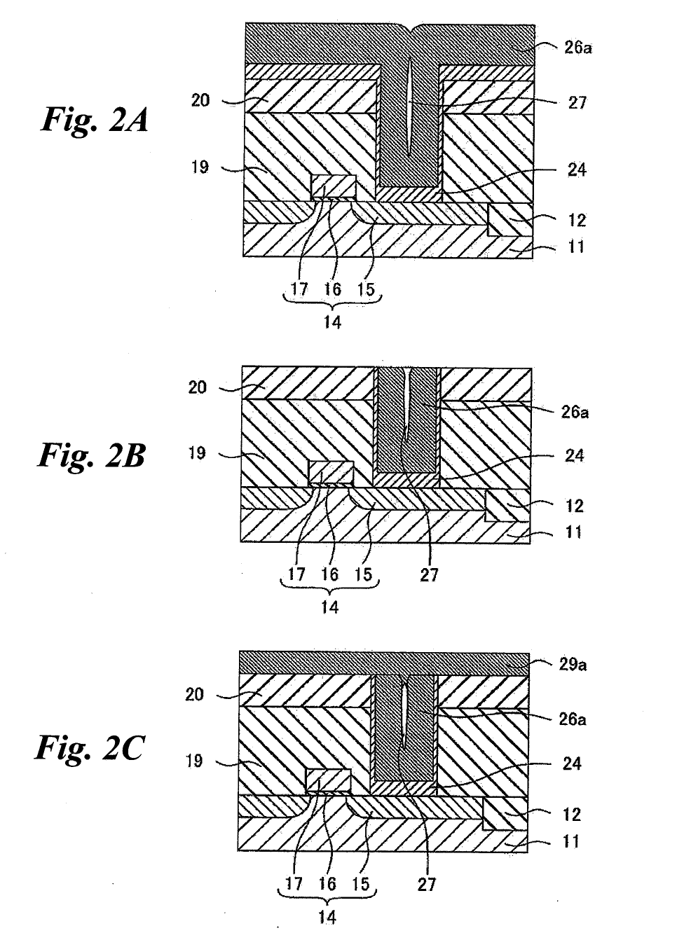

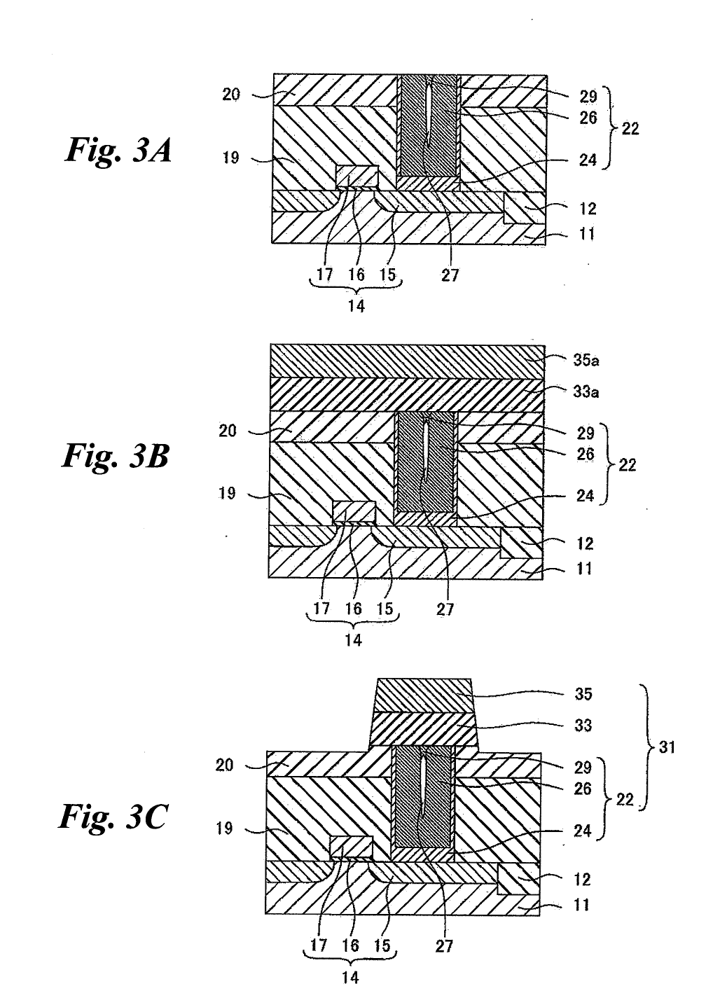

A semiconductor device according to Embodiment 1 of the invention is described hereinafter with reference to FIGS. 1 to 3C. FIG. 1 illustrates a cross-sectional view of this semiconductor device. FIGS. 2A to 2C illustrate cross-sectional views of sequential steps in a method for manufacturing this semiconductor device, which focuses on a plug lower-electrode thereof. FIGS. 3A to 3C illustrate cross-sectional views of sequential steps in the method for manufacturing this semiconductor device continuing from the steps illustrated in FIGS. 2A to 2C. In the following description, the direction away from the principle surface of the semiconductor substrate is assumed to the upper or upward direction in each of the drawings.

As illustrated in FIG. 1, a semiconductor device 1 includes a semiconductor substrate 11, a switching transistor 14 formed on the semiconductor substrate 11, interlayer insulating films 19 and 20 formed to cover the transistor 14, and a ferroelectric capacitor 31. The ferroelectric capacitor 31 includes a plug lower-electrode 22, a ferroelectric film 33 and an upper-electrode 35. The plug lower-electrode 22 has a contact plug function and passes through the interlayer insulating films 19 and 20, and the ferroelectric film 33 and the upper-electrode 35 has side surfaces formed perpendicular to the upper surface of the semiconductor substrate. At least a part of the interlayer insulating film 19 is a silicon oxide film, and the interlayer insulating film 20 has a high-barrier-performance. The side surfaces of the ferroelectric film 33, and the side surfaces and the upper surface of the upper-electrode 35 are covered with the barrier insulating film 37. Although not shown in FIG. 1, the semiconductor device 1 may have other plugs and wirings, and the like.

The semiconductor substrate 11 is, for example, a silicon substrate with a p-type element forming region on the upper surface thereof. In the p-type element forming region of the semiconductor substrate 11, n-type diffusion layers 15 serving as a source or a drain are formed so as to be separated from each other. A gate electrode 17 is formed on the semiconductor substrate 11 via a gate insulating film 1 at a location between the two diffusion layers 15. An element separation region 12 is formed to divide the diffusion layer 15. The semiconductor substrate 11 can also be configured so that p-type diffusion layers 15 are provided in an n-type element forming region.

The interlayer insulating film 19 is, e.g., a silicon oxide (SiOₓ, e.g., SiO₂) film, and covers the surfaces of the transistor 14 and the element region 12. The interlayer insulating film 20 is, e.g., an aluminum oxide (Al₂O₃) film, and suppresses/prevents the diffusion of component elements of the ferroelectric film 33 and the diffusion of hydrogen. As the interlayer insulating film 19, monolayer films of silicon oxide, aluminum oxide (Al₂O₃), or zirconium oxide (ZrO₂), or laminated layer films formed by combining at least two of the above monolayer films can be used. As the interlayer insulating film 20, monolayer films such as an Al₂O₃ film, a ZrO₂ film, titanium dioxide (TiO₂) film, and silicon nitride (SiNₓ) film, or laminated layer films formed by combining at least two of the monolayer films can be used. For example, “x” after an element in each of the chemical formulae indicates that the compositional ratio of that element is 1% or more.

The plug lower-electrode 22 is connected to the diffusion layer 15 of the transistor 14 at its bottom, and contacts the ferroelectric film 33 of the ferroelectric capacitor 31 at its top. The plug lower-electrode 22 has the functions of the contact plug and of the lower-electrode. At a plane parallel to the upper surface of the semiconductor substrate 11, the plug lower-electrode 22 may have a cross-sectional shape of a circle, an ellipse, or a corner-rounded rectangle. At a plane perpendicular to the upper surface of the semiconductor substrate 11, the plug lower-electrode 22 may have a cross-section shape of a rectangle or a trapezoid gradually decreased in width towards the bottom thereof, or the like.

The plug low-electrode 22 includes a barrier metal 24 and a plug metal 26. The barrier metal 24 made of a titanium aluminum nitride (TiAlN) film forms a side surface and a bottom of the plug low-electrode 22, and the barrier metal 24 is formed relatively thicker at the bottom portion than at the side surface portion. The plug metal 26 made of iridium (Ir) is provided at the inner portion of the plug lower-electrode 22 so as to be covered with the barrier metal. For example, is it possible to deposit titanium (Ti) between the diffusion layer 15 and the TiAlN film. As the plug metal 26, one of an Ir film, a Pt film, a strontium ruthanate (SrRuO₃) film and an iridium oxide (IrOₓ, e.g., IrO₂) film, which are highly oxidation-resistant, or a combination of at least of two of the above can be used. As the barrier metal 24, TiAlN, TiN, WN and the like can be used.

When the plug metal 26 is formed by depositing an Ir film, a void or a seam (both hereafter referred to as a seam 27) where not filled up with Ir is formed at a central location about an equal distance from the side surfaces of the plug lower-electrode 22. In this embodiment, at least the upper end portion of a seam 27 is filled in with a burying metal 29 that is made of the same Ir as the plug metal 26. In other words, the opening of the seam 27 at the upper surface of the plug metal 26 is closed up by the burying metal 29.

The plug lower-electrode 22 and the interlayer insulating film 20 are planarized so that the upper surfaces thereof are flush with each other, and the ferroelectric film 33 made of lead zirconate titanate oxide (Pb(ZrₓTi₁₋ₓ) O₃ (PZT)) is provided thereon. The upper-electrode 35 made of laminated layers of SrRuO₃ and IrO₂ is provided on the ferroelectric film 33. The side surfaces of the ferroelectric film 33 and the upper-electrode 35 form an angle of about 75 degrees to 90 degrees with respect to the upper surface of the semiconductor substrate 11, so that the area occupied by these can be reduced.

The barrier insulating film 37 is made of Al₂O₃ and covers the upper surface of the interlayer insulating film 20, the side surfaces of the ferroelectric film 33 and the upper-electrode 35 and the upper surface of the upper-electrode 35. The upper surface of the interlayer insulating film 20 is slightly lower than the bottom surface of the ferroelectric film 33 (closer to the semiconductor substrate 11) in the region not contacting the ferroelectric film 33. The upper surface of the barrier insulating film 37 is covered with the interlayer insulating film 39 formed of a silicon oxide film.

The upper-electrode 35 is connected to a via plug 41 made of aluminum (Al) which penetrates through the barrier insulating film 37 and the interlayer insulating film 39. The via plug 41 is connected to a plate line 43. Al, W, or Ir can be used as the material of the via plug 41.

Next, a method for manufacturing the semiconductor device 1 is described below. As illustrated in FIG. 2A, the transistor 14 is formed on the semiconductor substrate 11, the interlayer insulating films 19 and 20 are deposited, and an opening in which the plug lower-electrode 22 is to be formed is formed, for example, by known methods. Subsequently, the barrier metal 24 made of TiAlN is deposited in the opening for forming the plug lower-electrode 22 by a self-ionized plasma (SiP) type sputtering method or a chemical vapor deposition (CVD) method. Subsequently, a plug metal 26a made of Ir is deposited thereon by the CVD method. The thickness of the film of the plug metal 26a is set to be about ⅔ the width of the plug lower-electrode 22. Thus, the seam 27 is formed at the widthwise central portion of the plug lower-electrode 22.

As illustrated in FIG. 2B, the plug metal 26a is processed by a chemical mechanical polishing (CMP) method so as to be flush with the upper surface of the interlayer insulating film 20. As a result, the opening of the seam 27 at the exposed upper surface may become larger than that at the time of deposition of the plug metal 26a.

As illustrated in FIG. 2C, a burying metal 29a made of Ir is deposited on the upper surface of the plug metal 26a and the interlayer insulating film 20 by the sputtering method or the CVD method. As a result, at least around the opening at the upper surface of the planarized plug metal 26a, that is, the upper portion of the seam 27, is filled in with the burying metal 29a.

As illustrated in FIG. 3A, the burying metal 29a is processed by the CMP method so as to be flush with the upper surface of the interlayer insulating film 20. Thus, the plug lower-electrode 22, in which the upper portion of the seam 27 is filled with the burying metal 29, is formed so as to be flush with the upper surface of the interlayer insulating film 20.

As illustrated in FIG. 3B, a ferroelectric film 33a made of PZT is formed on the interlayer insulating film 20 and the plug lower-electrode 22, and the upper-electrode film 35a made of laminated layers of SrRuO₃ and IrO₂ is deposited on the ferroelectric film 33a.

As illustrated in FIG. 3C, the upper-electrode film 35a and the ferroelectric film 33a are sequentially etched by, e.g., a high-temperature reactive ion etching (RIE) method at a temperature of 350° C. using a patterned silicon oxide film mask (the drawing of which is omitted). The side surfaces of both the upper-electrode 35 and the ferroelectric film 33 are inclined at, e.g., about 85 degrees with respect to the upper surface of the semiconductor substrate 11. The region the interlayer insulating film 20 where not covered with the ferroelectric film 33 is slightly etched and becomes lower.

Subsequently, although illustration is omitted, a barrier insulating film 37 made of Al₂O₃ is deposited on the interlayer insulating film 20, the upper-electrode 35 and the ferroelectric film 33 by an atomic layer deposition (ALD) method. Then, an interlayer insulating film 39 including a silicon oxide film is deposited on the barrier insulating film 37. Next, as illustrated in FIG. 1, a via plug 41 is formed so as to penetrate through the interlayer insulating film 39 and the barrier insulating film 37. Then, a plate line 43 connected to the via plug 41 is provided. Subsequently, the semiconductor device 1 is completed through a wiring process.

As described above, in the semiconductor device 1, the plug lower-electrode 22 serving as a contact plug is connected to the transistor by penetrating through the interlayer insulating film 19 and the interlayer insulating film 20 serving as a barrier film. The plug lower-electrode 22 includes the barrier metal 24 provided in the bottom surface portion and the side surface portion thereof, highly-oxidation-resistant plug metal 26 provided inside of the barrier metal 24, and the burying metal 29 buried at least in the upper opening of the seam 27. The ferroelectric film 33 is formed on the contact plug 22, the upper-electrode 35 is formed on the ferroelectric film 33, and the ferroelectric film 33 and the upper-electrode 35 have side surfaces that are continuous with each other and that are inclined to have an angle with the semiconductor substrate 11 of 75 degrees to 90 degrees. And, the barrier insulating film 37 is formed to be in contact with the interlayer insulating film 20 and continuously covers the side surfaces of the ferroelectric film 33 and the upper-electrode 35 and the upper surface of the upper-electrode 35.

The semiconductor device 1 includes the plug lower-electrode 22 serving as both a contact plug and a lower-electrode of the ferroelectric capacitor 31. To form the plug lower-electrode 22, only one through-hole forming process is required. Thus, no misalignment occurs in the plug lower-electrode 22, and deterioration of characteristics and the like due to misalignment are not caused.

In the plug lower-electrode 22, the upper-opening of the seam 27 is filled so that the upper surface thereof is completely flat. Thus, the opening of the seam 27 continuing to the upper surface does not reach the ferroelectric film 33. Accordingly, deterioration of the crystallinity of the ferroelectric film 33 due to the opening can be prevented. Consequently, a ferroelectric capacitor 31 which stably maintains a predetermined capacity can be obtained.

In a case where a ferroelectric capacitor is formed by sequentially depositing a lower-electrode material, a ferroelectric film material and an upper-electrode material and by collectively etching them, the residue of the lower-electrode material possibly adheres to a side surface of the processed ferroelectric film as & fence. If such conductive residue adheres to the side surface of the ferroelectric film, leak is caused in the ferroelectric capacitor, thereby deteriorating a characteristic thereof.

In this embodiment, the plug lower-electrode 22 containing the Ir burying metal 29 is formed inside a through hole. Thus, the plug lower-electrode 22 is covered with the ferroelectric film 33 to be formed thereon and is not processed by the high-temperature RIE method. Accordingly, the residue adhering to the side surface of the ferroelectric capacitor as a result of performing the high-temperature RIE method on the lower-electrode can be suppressed, thereby reducing the leakage in the ferroelectric capacitor 31. Because Ir is highly oxidation resistant and chemically stable, when the ferroelectric film 33 is formed, a reaction is suppressed even in a film forming atmosphere.

When the etching object is etching-processed so that the finished object has an inclined side surface, the occupying area (lower end area) of the finished object increases as a thickness of the etching object increases. In view of such process shift, when a ferroelectric capacitor is formed by collectively etching the upper-electrode material, the ferroelectric film material and the lower-electrode material, since total thickness of the etching object is increased, the occupying area of the finished ferroelectric capacitor is increased.

In this embodiment, since the ferroelectric capacitor is formed by etching only the upper-electrode material and the ferroelectric film material, the occupying area of the ferroelectric capacitor can be reduced with respect to a given mask area.

The side surfaces of the ferroelectric capacitor 31, which are located above the interlayer insulating film 20, are formed from the ferroelectric film 33 and the upper-electrode 35. As a result, during the high-temperature RIE, the side-etching that forms concavities in the side surface is restrained. Accordingly, the barrier insulating film 37 can be deposited on the surfaces of the ferroelectric film 33 and the upper-electrode 35 so that there is no portion where the thickness of the barrier insulating film 37 is extremely thin. Consequently, hydrogen diffusion and the like can be surely prevented.

### Embodiment 2

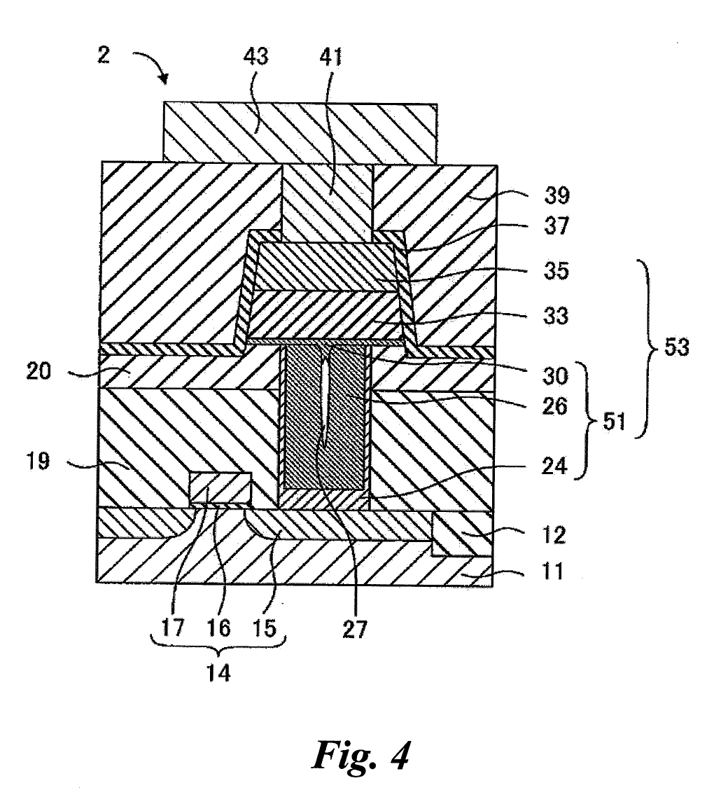

A semiconductor device according to Embodiment 2 of the invention is described hereinafter with reference to FIG. 4. FIG. 4 illustrates a cross-sectional view of the semiconductor device according to Embodiment 2. The semiconductor device according to Embodiment 2 differs from the semiconductor device according to Embodiment 1 in that the burying metal left thicker so that an upper surface thereof corresponds to a bottom surface of the ferroelectric film. The same constituent elements as those of Embodiment 1 are designated with the same reference numeral. The description of such constituent elements is omitted.

As illustrated in FIG. 4, a semiconductor device 2 includes a burying metal plate 30 made of Ir. The burying metal plate 30 includes a burying portion blocking up the opening of the seam 27 and a plate-like portion extending under the bottom surface of the ferroelectric film 33. The thickness of the burying metal plate 30 is 50 nm or less. The configuration of the ferroelectric capacitor 53 according to Embodiment 2 is similar to that of the ferroelectric capacitor 31 according to Embodiment 1 except that the burying metal plate 30 is provided in the ferroelectric capacitor 53. The burying metal plate 30 is configured so that a plate like portion made of Ir is deposited on the burying metal 29 according to Embodiment 1.

Next, a method for manufacturing the semiconductor device 2 is described below. The method up to the step illustrated in FIG. 2C is similar to that in the method according to Embodiment 1. At the step illustrated in FIG. 2C, the thickness of the burying metal 29a formed on the interlayer insulating film 20 is set at about 50 nm. At least the opening of the seam 27, i.e., the upper portion of the seam 27, which is slightly lower than the upper surface of the plug metal 26a, is filled with the burying metal 29a made of Ir. Thus, the upper surface of the burying metal 29a becomes substantially flat. For example, the burying metal 29a may be deposited on the interlayer insulating film 20 so as to have a thickness larger than about 50 nm, and then, the burying metal 29a may be processed by the CMP method or the like so as to have a thickness of about 50 nm or less.

As the step illustrated in FIG. 3B, without undergoing processing similar to the step illustrated in FIG. 3A according to Embodiment 1, a ferroelectric film 33a made of PZT is deposited on the burying metal 29a that is left over the upper surface. And, the upper-electrode film 35a in which SrRuO₃ and IrO₂ layers are stacked is deposited on the ferroelectric film 33a. For example, the burying metal 29a may be processed through a step similar to the step illustrated in FIG. 3A according to Embodiment 1, i.e., by the CMP method so as to be flush with the upper surface of the interlayer insulating film 20, a plate-like film made of Ir having a thickness of about 50 nm may be deposited thereon, and the burying metal plate 30 may be formed by joining the burying metal blocking up the opening of the seam 27 with the plate-like film Ir.

Subsequently, as the step illustrated in FIG. 3C according to Embodiment 1, the upper-electrode film 35a, the ferroelectric film 33a and the burying metal 29a are sequentially etched by the high-temperature RIE method at 350° C. The subsequent steps are similar to those of the method according to Embodiment 1. Consequently, the semiconductor device 2 having the ferroelectric capacitor 53 is completed.

The semiconductor device 2 has the burying metal plate 30 which is in contact with the bottom surface of the ferroelectric film 33 and is fairly thin compared with the lower-electrode of the related-art semiconductor device (e.g., about ⅓ the thickness of the latter). When the burying metal plate 30 is subjected to the high-temperature RIE processing, a conductive residue of the burying meal plate 30 might adheres to a side surface of the ferroelectric capacitor. However, because the burying metal plate 30 is thin, an amount of the residue is relatively small, and the leakage of the ferroelectric capacitor 31 is maintained at a relatively low level. Further, since the burying metal plate 30 is thin, affection of process shift is small. On the other hand, since the contacting area between the lower-electrode and the ferroelectric film is enlarged, the capacity of the ferroelectric capacitor is increased. Accordingly, the semiconductor device 2 in improved in characteristics, e.g., the signal magnitude.

The semiconductor device 2 also has the advantages as the semiconductor device 1 according to Embodiment 1.

### Embodiment 3

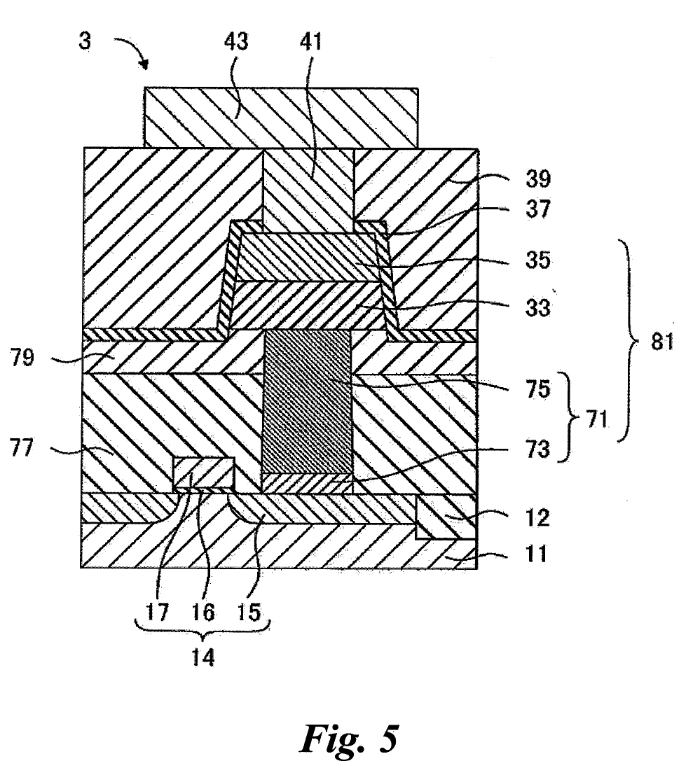

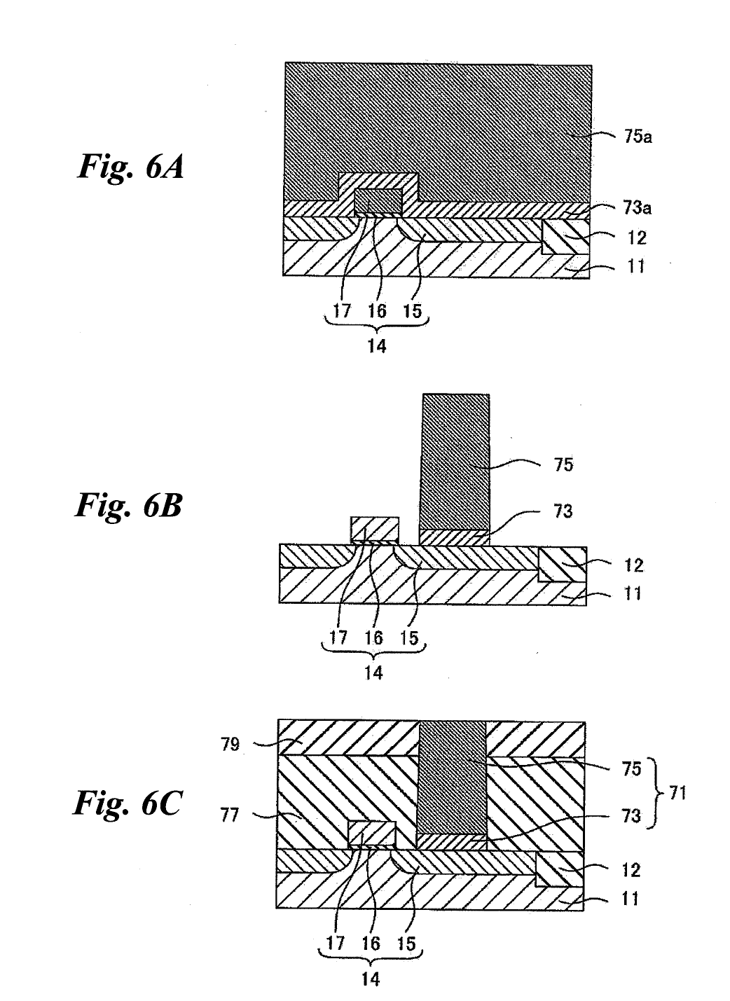

A semiconductor device according to Embodiment 3 of the invention is described with reference to FIGS. 5 to 6C. FIG. 5 illustrates a cross-sectional view of the semiconductor device according to Embodiment 3. FIGS. 6A to 6C illustrate cross-sectional views of sequential steps in a method for manufacturing the semiconductor device according to Embodiment 3, focusing on formation of the plug lower-electrode. The semiconductor device according Embodiment 3 differs from the semiconductor device 1 according to Embodiment 1 in that a plug lower-electrode substantially does not contain a seam. The same constituent elements as those of Embodiment 1 and Embodiment 2 are designated with the same reference numeral. The description of such constituent elements is omitted.

As illustrated in FIG. 5, a plug lower-electrode 71 includes a relatively thick barrier metal 73 and a plug metal 75. The barrier metal 73 is made of Ti and TiAlN, and a thickness thereof is close to that of the bottom surface portion of the barrier metal 24 according to Embodiment 1. The plug metal 75 made of Ir is provided on the barrier metal 73. As will be described below, differently from Embodiment 1 and Embodiment 2, the plug lower-electrode 71 is formed not by forming a large-aspect-ratio through hole in an interlayer insulating film and by filing the through hole with the plug metal. Thus, no seam is generated in the plug metal 75. At a plane parallel to the upper surface of the semiconductor substrate 11, the plug lower-electrode 71 may have a cross-section shape of a circle, an ellipse, a corner-rounded rectangle, or the like. At a plane perpendicular to the upper surface of the semiconductor substrate 11, the plug lower-electrode 71 may have a cross-section shape of a rectangle or a trapezoid gradually decreased in width towards the top thereof, or the like.

Next, a method for manufacturing the semiconductor device 3 is described below. This method differs from the method according to Embodiment 1 mainly in that the plug lower-electrode is formed first, and then an interlayer insulating film is formed therearound.

As illustrated in FIG. 6A, after a transistor 14 is formed on the semiconductor substrate 11, a barrier metal 73a made of Ti and TiAlN is deposited on the semiconductor substrate 11 and then a plug metal 75a made of Ir is deposited on the barrier metal 73a, so as to cover the transistor 14

As illustrated in FIG. 6B, the plug metal 75a and then the barrier metal 73a is processed by the RIE method using a patterned Al₂O₃ mask (not shown) so as to form a plug lower-electrode 71 of the columnar shape gradually reduced in a width (diameter) towards the top thereof. Subsequently, the mask is removed.

As illustrated in FIG. 6C, the space around the columnar shape of the barrier metal 73 and the plug metal 75 is filled with an interlayer insulating film 77. After the upper surface is planarized, the interlayer insulating film 77 is processed by the RIE method so that its upper surface is lower than the upper surface of the plug metal 75. Subsequently, this space is filled with an interlayer insulating film 79, and planarization is performed by, e.g., the CMP method, so that the upper surface of the interlayer insulating film 79 is flush with the plug metal 75. The materials of the interlayer insulating films 77 and 79 respectively correspond to those of the interlayer insulating films 19 and 20 according to Embodiment 1.

A cross-sectional structure illustrated in FIG. 6C corresponds to that illustrated in FIG. 3A of Embodiment 1. Thus, the subsequent processing is similar to that for manufacturing the semiconductor device 1 according to Embodiment 1. Consequently, a semiconductor 3 having a ferroelectric capacitor 81 is completed.

In the semiconductor device 3, the plug lower-metal 71 is formed by depositing the barrier metal 73a and the plug metal 75a and processing them into the columnar shape of the plug metal 75 and the barrier metal 73. Thus, differently form Embodiment 1, no seam is formed. When the seam is formed on the plug metal and the ferroelectric film is directly formed thereon, the crystallinity of the ferroelectric film will be deteriorated. In this embodiment, since no seam is formed, the deterioration of the crystallinity of the ferroelectric film 33 due to the seam on the plug metal is not caused at all, and the ferroelectric film 33 is good in crystallinity so that a ferroelectric capacitor 81 stably exhibits a given capacity.

The semiconductor device 3 also has the advantages as the semiconductor device 1 according to Embodiment 1.

The invention is not limited to the aforementioned embodiments. The invention can be implemented by variously being modified without departing from the spirit thereof.

For example, each embodiment has the device including a switching transistor, a plug lower-electrode and a ferroelectric capacitor. However, the embodiments can also be adapted to, for example, a chain-type FeRAM (series connected TC unit type ferroelectric RAM) in which a cell array block is constituted by series-connecting a plurality of cells each containing a transistor and a ferroelectric capacitor connected in parallel.

In the embodiments, a PZT film is used as a ferroelectric film. However, for example, another perovskite-type crystal structure, e.g., a PZLT ((lanthanum-doped lead zirconium titanate) ((Pb, La)ₓ (Zr, Ti)₁₋ₓO₃)) or SBT (SrBi₂Ta₂O₉) can be used.

According to an aspect of the present invention, there is provided a semiconductor device capable of suppressing the influence of a seam and being formed without plug misalignment.

What is claimed is:

1. A semiconductor device, comprising:
a semiconductor substrate;
a transistor that on the semiconductor substrate;
an interlayer insulating film over the transistor on the semiconductor substrate and comprising a through hole inside the interlayer insulating film configured to connect to the transistor;
a plug lower-electrode in the through hole connected to the transistor;
a ferroelectric film on the plug lower-electrode; and
an upper-electrode on the ferroelectric film.

2. The semiconductor device of claim 1,
wherein the plug lower-electrode is in the through hole of the interlayer insulating film, and
wherein the plug lower-electrode comprises:
a barrier metal over a bottom surface and a side surface of the through hole;
a plug metal inside the barrier metal and comprising a seam on an upper portion of the plug metal; and
a burying metal in the seam.

3. The semiconductor device of claim 2,
wherein the plug metal and the burying metal comprise the same material.

4. The semiconductor device of claim 1,
wherein the plug lower-electrode is in the through hole of the interlayer insulating film, and
wherein the plug lower-electrode comprises:
a barrier metal over a bottom surface and a side surface of the through hole;
a plug metal inside the barrier metal and comprising a seam on an upper portion of the plug metal; and
a burying metal plate in the seam extending on an upper surface of the interlayer insulating film in a plate-like shape.

5. The semiconductor device of claim 4,
wherein the plug metal and the burying metal plate comprise the same material.

6. The semiconductor device of claim 4,
wherein the burying metal plate comprises a T-letter-like shape, from a lateral view.

7. The semiconductor device of claim 4,
wherein the burying metal plate is continuously with the ferroelectric film.

8. The semiconductor device of claim 4,
wherein the ferroelectric film is on an upper surface of the burying metal plate.

9. The semiconductor device of claim 1,
wherein the plug lower-electrode is in the through hole of the interlayer insulating film, and
wherein the plug lower-electrode comprises:
a barrier metal on a bottom surface of the through hole; and
a plug metal on the barrier metal configured to connect with a side surface of the through hole.

10. The semiconductor device of claim 1,
wherein the interlayer insulating film comprises:
a first interlayer insulating film over the transistor on the semiconductor substrate; and
a second interlayer insulating film on the first interlayer insulating film configured to suppress a diffusion of oxygen.

11. The semiconductor device of claim 10,
wherein the second interlayer insulating film comprises at least one film selected from a group consisting of:
an aluminum oxide (Al₂O₃) film;
a zirconium dioxide (ZrO₂) film;
a titanium dioxide (TiO₂) film; and
a silicon nitride (SiN₁₀ film.

12. The semiconductor device of claim 10,
wherein the second interlayer insulating film comprises at least two films selected from a group consisting of:
an Al₂O₃ film;
a ZrO₂ film;
a TiO₂ film; and
an SiNₓ film.

13. The semiconductor device of claim 10,
wherein the first interlayer insulating film comprises at least one film selected from a group consisting of:
an SiO₂ film;
an Al₂O₃ film; and
a ZrO₂ film.

14. The semiconductor device of claim 10,
wherein the first interlayer insulating film comprises at least two films selected from a group consisting of:
an SiO₂ film;
an Al₂O₃ film; and
a ZrO₂ film.

15. The semiconductor device of claim 1,
wherein the plug lower-electrode comprises a highly-oxidation-resistant metal.

16. The semiconductor device of claim 1,
wherein a side surface of the ferroelectric film is continuous with a side surface of the upper-electrode, and
wherein an angle between the side surfaces of the ferroelectric film and the plug lower-electrode is equal to or larger than 75 degrees and smaller than or equal to 90 degrees with respect to a main surface of the semiconductor substrate.

17. The semiconductor device of claim 1, further comprising:
a barrier insulating film continuously over an upper surface of the interlayer insulating film, a side surface of the ferroelectric film, and side and upper surfaces of the upper-electrode.

18. The semiconductor device of claim 1,
wherein the plug lower-electrode comprises a barrier metal and a plug metal, and
wherein the plug metal comprises at least one material selected from a group consisting of:
iridium (Ir);
platinum (Pt);
strontium ruthenium oxide (SrRuO₂); and
iridium oxide (IrOₓ).

19. The semiconductor device of claim 1,
wherein the plug lower-electrode comprises a barrier metal and a plug metal, and
wherein the barrier metal comprises at least one material selected from a group consisting of:
titanium aluminum nitride (TiAlN);
titanium nitride (TiN); and
tungsten nitride (WN).
